(19) United States
(12) Patent Application Publication
(10) Pub. No.: US 2026/0190392 A1
(43) Pub. Date: Jul. 2, 2026

(54) TECHNOLOGIES FOR STRAIN ENGINEERING IN GATE-ALL-AROUND TRANSISTORS

(71) Applicant: Intel Corporation, Santa Clara, CA (US)

(72) Inventors: Gilbert Dewey, Beaverton, OR (US); Seung Hoon Sung, Portland, OR (US); Wriddhi Chakraborty, Hillsboro, OR (US); Ashish Agrawal, Hillsboro, OR (US); Nazila Haratipour, Portland, OR (US); Nancy Zelick, Portland, OR (US); Neda Dalili, Portland, OR (US); Lukas Baumgartel, Portland, OR (US); Arnab Sen Gupta, Hillsboro, OR (US); Stephen M. Cea, Hillsboro, OR (US); Rohit V. Galatage, Portland, OR (US)

(73) Assignee: Intel Corporation, Santa Clara, CA (US)

(21) Appl. No.: 19/002,586

(22) Filed: Dec. 26, 2024

(51) Int. Cl. H10D 30/67; H10D 30/00; H10D 30/01; H10D 30/47; H10D 62/10; H10D 62/13; H10D 84/83

(52) U.S. Cl. CPC H10D 30/6735; H10D 30/0191; H10D 30/47; H10D 30/502; H10D 30/6757; H10D 62/118; H10D 62/151; H10D 84/832

(57) ABSTRACT

Technologies for strain engineering in gate-all-around (GAA) field-effect transistors (FETs) are disclosed. In an illustrative embodiment, the source/drain contacts for N-type metal-oxide-semiconductor (NMOS) FETs extend deeper into the source/drain regions than the source/drain contacts for P-type metal-oxide-semiconductor (PMOS) FETs. The source/drain contacts for the NMOS FETs may cause a tensile strain in the channel of the NMOS FETs, while the source/drain region of the PMOS FETS may cause a compressive strain in the channel of the PMOS FETs. The tensile and compressive strains on the NMOS and PMOS channels, respectively, can increase the speed of the NMOS and PMOS transistors.

### BACKGROUND

Transistors are ubiquitous devices present in virtually all electronic devices. As the density of transistors continues to increase, new architectures such as fin field effect transistors (FETs) and gate-all-around (GAA) FETs are used to reduce the footprint of a transistor. A GAA FET may include several nanoribbons or nanowires vertically stacked on top of each other. In many transistors, such as fin FETs, the channel for NMOS transistors may be under tensile strain, and the channel for PMOS transistors may be under compressive strain. The tensile strain for NMOS transistors and compressive strain for PMOS transistors can increase carrier mobility in the channels. However, the techniques for strain engineering in fin FET transistors may not be applicable to GAA FETs.

### BRIEF DESCRIPTION OF THE DRAWINGS

FIG. 1 is an isometric view of a gate-all-around field-effect transistor.

FIG. 2 is a cross-sectional side view of one embodiment of the transistor of FIG. 1.

FIG. 3 is a cross-sectional side view of one embodiment of the transistor of FIG. 1.

FIG. 4 is a cross-sectional side view of one embodiment of the transistor of FIG. 1.

FIG. 5 is a cross-sectional side view of one embodiment of the transistor of FIG. 1.

FIG. 6 is a cross-sectional side view of one embodiment of the transistor of FIG. 1.

FIG. 7 is a simplified flow diagram of at least one embodiment of a method for creating the transistor of FIG. 1.

FIG. 8 is a cross-sectional side view at one step of one embodiment of the flow diagram of FIG. 5.

FIG. 9 is a cross-sectional side view at one step of one embodiment of the flow diagram of FIG. 5.

FIG. 10A is a cross-sectional side view at one step of one embodiment of the flow diagram of FIG. 5.

FIG. 10B is a cross-sectional side view at one step of one embodiment of the flow diagram of FIG. 5.

FIG. 11A is a cross-sectional side view at one step of one embodiment of the flow diagram of FIG. 5.

FIG. 11B is a cross-sectional side view at one step of one embodiment of the flow diagram of FIG. 5.

FIG. 12A is a cross-sectional side view at one step of one embodiment of the flow diagram of FIG. 5.

FIG. 12B is a cross-sectional side view at one step of one embodiment of the flow diagram of FIG. 5.

FIG. 13A is a cross-sectional side view at one step of one embodiment of the flow diagram of FIG. 5.

FIG. 13B is a cross-sectional side view at one step of one embodiment of the flow diagram of FIG. 5.

FIG. 14A is a cross-sectional side view at one step of one embodiment of the flow diagram of FIG. 5.

FIG. 14B is a cross-sectional side view at one step of one embodiment of the flow diagram of FIG. 5.

FIG. 15 is a cross-sectional side view of one embodiment of the transistor of FIG. 1.

FIG. 16 is a cross-sectional side view of one embodiment of the transistor of FIG. 1.

FIG. 17 is a top view of a wafer and dies that may be included in a microelectronic assembly in accordance with any of the embodiments disclosed herein.

FIG. 18 is a cross-sectional side view of an integrated circuit device that may be included in any of the microelectronic assemblies disclosed herein.

FIGS. 19A-19D are perspective views of example planar, FinFET, gate-all-around, and stacked gate-all-around transistors.

FIG. 20 is a cross-sectional side view of an integrated circuit device assembly that may include a microelectronic assembly in accordance with any of the embodiments disclosed herein.

FIG. 21 is a block diagram of an example electrical device that may include a microelectronic assembly in accordance with any of the embodiments disclosed herein.

### DETAILED DESCRIPTION

In one embodiment disclosed herein, as described in more detail below, a channel region of an n-type metal-oxide-semiconductor (NMOS) gate-all-around (GAA) field effect transistor (FET) is under a tensile strain, and a channel region of a p-type metal-oxide-semiconductor (PMOS) GAA FET is under a compressive strain. In an illustrative embodiment, the NMOS FET is under a tensile strain due to deep source/drain contacts in the source/drain regions that pull the source/drain regions away from the channel regions, putting the channel regions under a tensile strain. The illustrative PMOS FET is under a compressive strain due to the source/drain regions themselves, which may be boron-doped silicon-germanium. The source/drain regions of the PMOS FET may push on the channel regions, putting the channel regions under a compressive strain. In the illustrative PMOS FET, the source/drain contact is shallow in order to not interfere with the compressive strain caused by the source/drain regions. The tensile strain in the channels of the NMOS FET and the compressive strain in the channels of the PMOS FET may increase the operation speed of the transistors by, e.g., 25-30%, compared to transistors without strained channels.

In other transistor designs, such as fin FETs, strain on the channel may be imparted by the source/drain epitaxial growth and lattice mismatch. In some embodiments, the same approach may be applied to embodiments disclosed herein, in additional to other techniques disclosed herein. However, in a GAA architecture, strain from the epitaxial source/drain may have some technical challenges for imparting large performance-enhancing strain, particularly for NMOS FETs. For example, when growing source/drain regions epitaxially from multiple nanosheets, defects may form where the different epitaxially grown regions merge, and the defects may release some or all of the strain.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner.

“Connected” may indicate elements are in direct physical or electrical contact with each other and “coupled” may indicate elements cooperate or interact with each other, but they may or may not be in direct physical or electrical contact. Furthermore, the terms “comprising,” “including,” “having,” and the like, as used with respect to embodiments of the present disclosure, are synonymous.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components. As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y. As used herein, the phrase “electrically coupled” refers to the presence of one or more electrically conductive paths between components that are recited as being electrically coupled.

Certain terminology may also be used herein for the purpose of reference only, and thus are not intended to be limiting. For example, terms such as “upper,” “lower,” “above,” “below,” “bottom,” and “top” refer to directions in the Figures to which reference is made. Terms such as “front,” “back,” “rear,” and “side” describe the orientation and/or location of layers, components, portions of components, etc., within a consistent but arbitrary frame of reference, which is made clear by reference to the text and the associated Figures describing the layers, component, portions of components, etc. under discussion. Such terminology may include the words specifically mentioned above, derivatives thereof, and words of similar import.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

As used herein, the term “electronic component” can refer to an active electronic component (e.g., processing unit, memory, storage device, transistor) or a passive electronic component (e.g., resistor, inductor, capacitor).

As used herein, the terms “operating,” “executing,” or “running” as they pertain to software or firmware in relation to a system, device, platform, or resource are used interchangeably and can refer to software or firmware stored in one or more computer-readable storage media accessible by the system, device, platform or resource, even though the software or firmware instructions are not actively being executed by the system, device, platform, or resource.

Reference is now made to the drawings, which are not necessarily drawn to scale, wherein similar or the same numbers may be used to designate the same or similar parts in different figures. The use of similar or the same numbers in different figures does not mean all figures including similar or the same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

As used in this application and the claims, a list of items joined by the term “and/or” can mean any combination of the listed items. For example, the phrase “A, B, and/or C” can mean A; B; C; A and B; A and C; B and C; or A, B and C. As used in this application and the claims, a list of items joined by the term “at least one of” can mean any combination of the listed terms. For example, the phrase “at least one of A, B, or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B, and C” can mean A; B; C; A and B; A and C; B and C; or A, B, and C.

As used in this application and the claims, the phrase “individual of” or “respective of” followed by a list of items recited or stated as having a trait, feature, etc., means that all of the items in the list possess the stated or recited trait, feature, etc. For example, the phrase “individual of A, B, or C, comprise a sidewall” or “respective of A, B, or C, comprise a sidewall” means that A comprises a sidewall, B comprises a sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

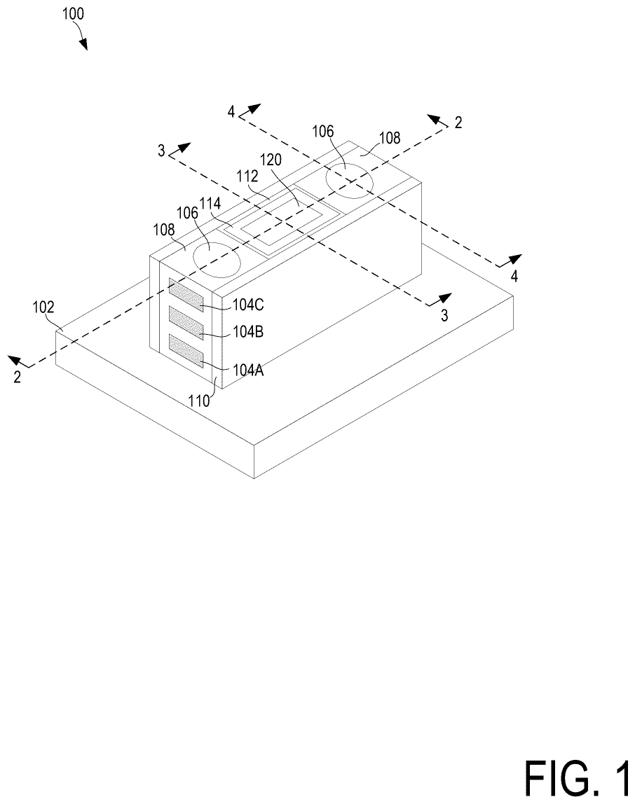

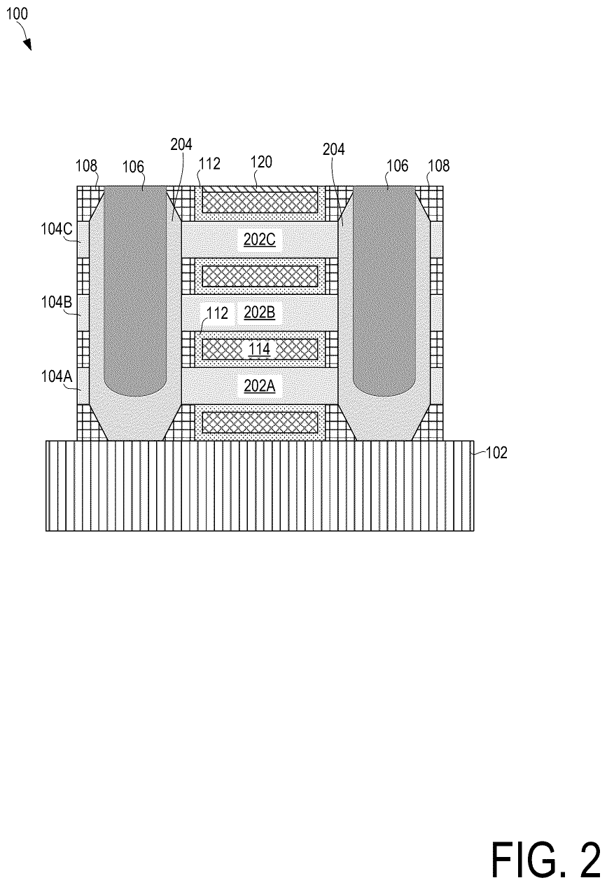

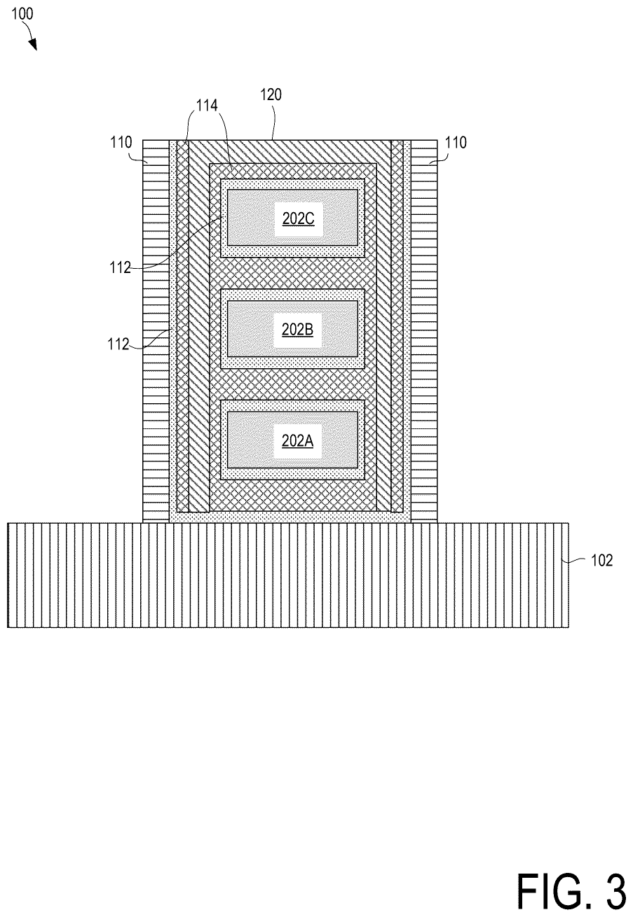

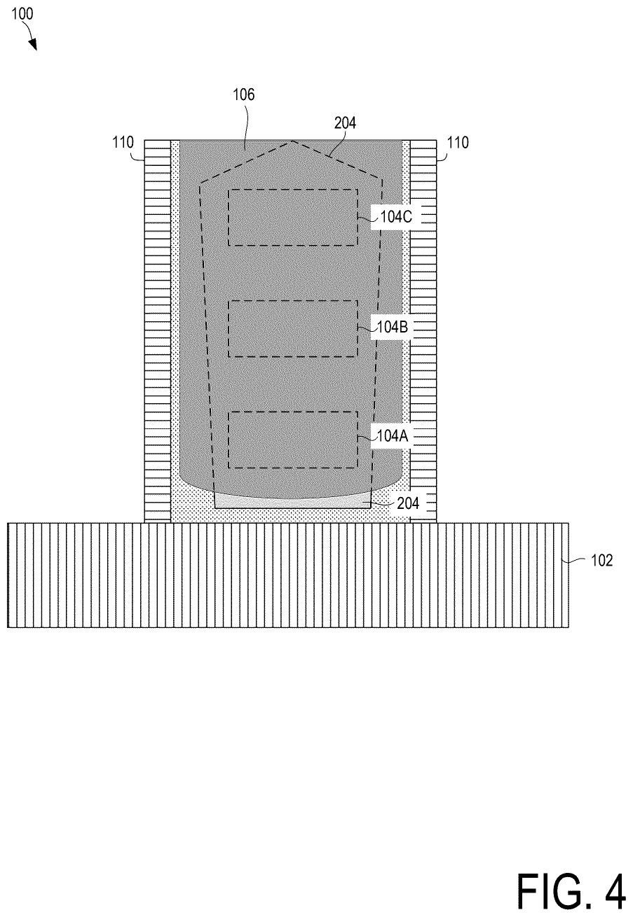

Referring now to FIGS. 1-4, in one embodiment, FIG. 1 shows a perspective view of a GAA FET 100, FIG. 2 shows a cross-sectional view of the GAA FET 100 taken from view 2 labeled in FIG. 1, FIG. 3 shows a cross-sectional view of the GAA FET 100 taken from view 3 labeled in FIG. 1, and FIG. 4 shows a cross-sectional view of the GAA FET 100 taken from view 4 labeled in FIG. 1. In some embodiments, the GAA FET 100 may also be referred to as a ribbon FET transistor, a nanoribbon transistor, a nanowire transistor, a nanosheet transistor, etc. In an illustrative embodiment, the GAA FET 100 is an NMOS GAA FET 100.

The GAA FET 100 is supported by a substrate 102 of a die. The GAA FET 100 has one or more semiconductor nanoribbons 104A, 104B, and 104C. The semiconductor nanoribbons 104A-C include channel regions 202A, 202B, and 202C (see FIGS. 2 and 3). Source/drain regions 204 are on either side of the channel regions 202A-C. Dielectric spacers 108 are in between the source/drain regions 204 and the region with the channel regions 202A-C, gate 114, and gate dielectric layer 112. A gate dielectric layer 112 surrounds the channel regions 202A-C inside the region bounded by the dielectric spacers 108 and the dielectric isolation layers 110. The gate 114 surrounds the gate dielectric layer 112 and the channel regions 202A-C. A conductive material 120 is on top of the gate 114. Dielectric isolation layers 110 surround the channel regions 202A-C and other structures of the GAA FET 100. A contact 106 extends into each source/drain region 204.

As described in more detail below, the contacts 106 of the NMOS FET 100 are formed in a manner such that they contract after initial formation, pulling in on the source/drain regions 204 around them and putting the channel regions 202A-C under tension. The channel regions 202A-C may be under tension to increase the lattice constant in the dimension extending from one contact 106 to the other contact 106 by, e.g., 0.5-2%. In an illustrative embodiment, the lattice constant in that dimension may be increased by about 1.5%. In an illustrative embodiment, the channel region 202A-C is silicon, which may have a lattice constant, before strain is applied, of 0.5431 nanometers. The strain may increase the lattice constant in the dimension extending from one contact 106 to the other contact 106 to, e.g., 0.5458-0.5540 nanometers.

The substrate 102 supports the rest of the GAA FET 100. In the illustrative embodiment, the substrate 102 is silicon. In other embodiments, the substrate 102 may be, e.g., silicon oxide, gallium nitride, a perovskite, strontium titanium oxide, etc.

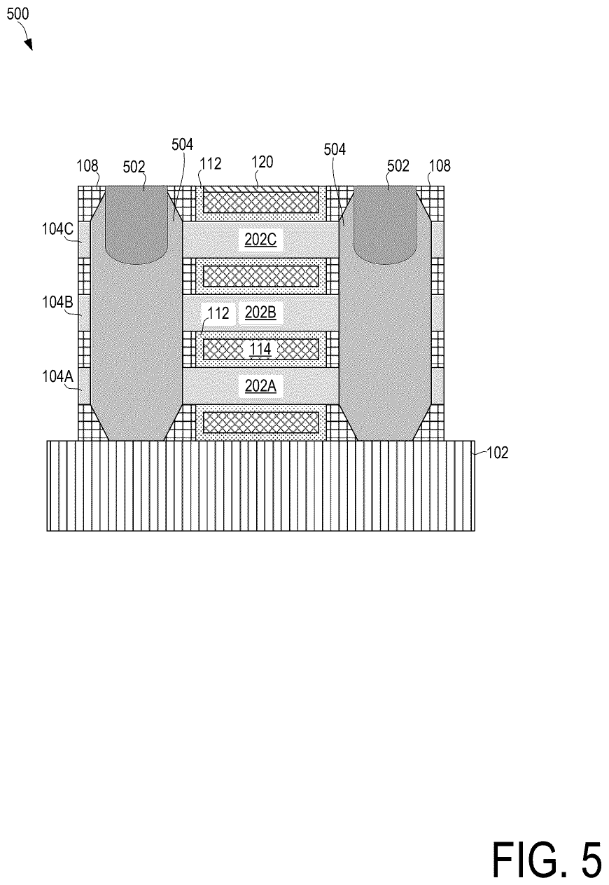

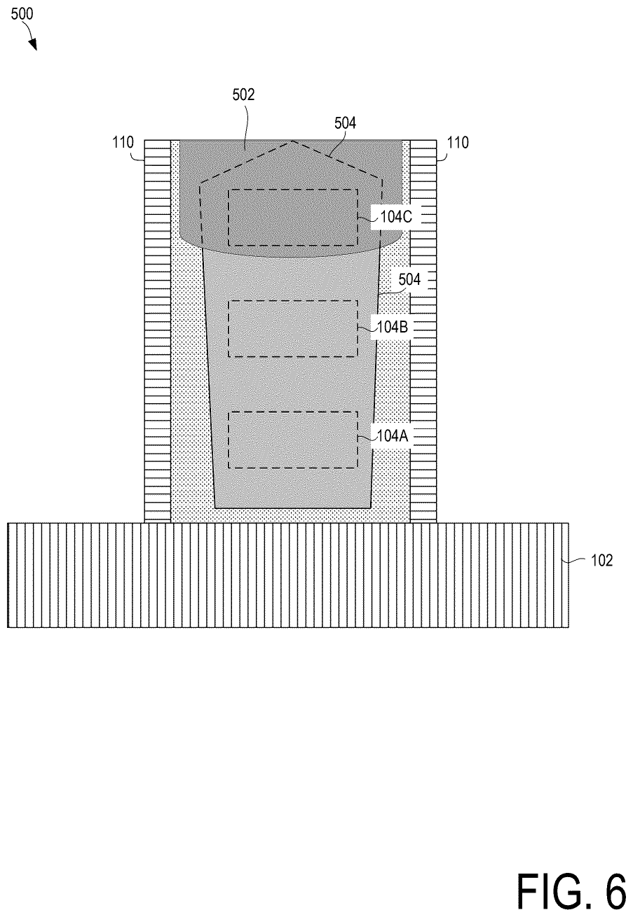

In the illustrative embodiment, the GAA FET 100 is an NMOS transistor. A corresponding PMOS GAA FET 500 is described below in regard to FIGS. 5 and 6. The semiconductor nanoribbons 104A-C may be made from any suitable material or combination of materials, such as undoped or lightly doped semiconductor. In the illustrative embodiment, the channel regions 202A-C and the nanoribbons 104A-C are undoped or lightly doped silicon, such as silicon with a dopant concentration of less than, e.g., 10¹⁵-10¹⁹ cm⁻³. The channel regions 202A-C may refer to regions of the nanoribbons 104A-C that are surrounded by the gate dielectric layer 112 and gate 114 as well as to regions of the nanoribbons 104A-C that extend further, into regions dielectric isolation layers 110 separated by the dielectric spacers 108 and the dielectric isolation layers 110. In an illustrative embodiment, the channel region 202A-C refers to the region of the nanoribbons 104A-C between the source-drain regions 204. The illustrative source/drain regions 204 are silicon doped with, e.g., phosphorous or arsenic. More generally, the source/drain regions 204 and channel regions 202A-C or other part of the nanoribbons 104A-C may be made of any suitable combination of doped or undoped semiconductors, such a silicon, silicon-germanium, germanium, germanium-tin alloys, germanium-silicon-tin alloys, a III-V semiconductor, a perovskite, a compound semiconductor, etc. The source/drain regions 204 may have any suitable concentration of any suitable dopant, such as a dopant concentration of 10¹⁷-10²³ cm⁻³ of phosphorous, arsenic, antimony, and/or the like.

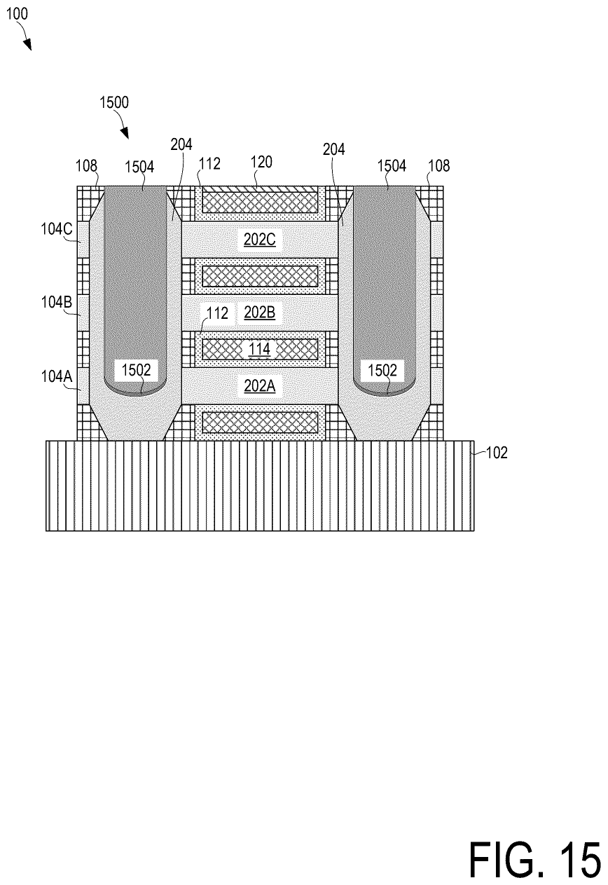

The contacts 106 adjacent the source/drain regions 204 of the NMOS FET 100 may be any suitable material, such as molybdenum, tungsten, titanium, titanium nitride, tungsten-carbon-nitride, aluminum-tungsten-carbide, molybdenum nitride, molybdenum carbide, and/or the like. In some embodiments, the contact 106 may be a multi-layer contact, as discussed below in regard to FIG. 15. The contacts 106 may be connected to one or more redistribution or interconnect layers. The contacts 106 may extend any suitable depth into the source/drain regions 204, such as 10-50 nanometers or deeper. In an illustrative embodiment, the contacts 106 may extend to a depth that is at least as deep as one or more of the nanoribbons 104A-C. For example, the contacts 106 may extend at least as deep as the second nanoribbon 104B, the third nanoribbon 104A, or, in embodiments with more nanoribbons, down to nanoribbons 104 deeper into the stack. In some embodiments, the contacts 106 may extend deeper than the source/drain regions 204 and/or deeper than any of the channels 104.

In the illustrative embodiment, the GAA FET 100 is symmetric, and there is no structural distinction between, e.g., the source of the GAA FET 100 and the drain of the GAA FET 100. As such, the source/drain region 204 may be the source region or the drain region. Accordingly, as used herein, a “source or drain region” may refer to a region that may act as the source of a transistor or to a region that may act as the drain of a transistor.

The nanoribbon 104A-C and channel regions 202A-C, B, 204D-E may have any suitable dimensions, such as a thickness or width of, e.g., 0.5-20 nanometers and a length of, e.g., 2-50 nanometers. The source/drain regions 204 may have any suitable dimensions, such as a width (into/out of the page) of 10-70 nanometers. The source/drain regions 204 may have any suitable length (across the page) of 5-50 nanometers. The source/drain regions 204 may have any suitable height, such as a height of 10-100 nanometers. The GAA FET 100 may include any suitable number of semiconductor nanoribbons 104A-C, such as 1-8.

In the illustrative embodiment, the dielectric spacers 108 are a low-k material such as, e.g., silicon oxide or silicon nitride. The dielectric isolation layers 110 may be made of any suitable material, such as silicon oxide or silicon nitride. The dielectric isolation layers 110 may have any suitable dimension, such as a length along the substrate 102 of, e.g., 2-50 nanometers, a height of, e.g., 5-50 nanometers, and a width of, e.g., 2-30 nanometers.

The gate dielectric layer 112 may be any suitable dielectric, such as a high-K dielectric. In the illustrative embodiment, the gate dielectric layer is hafnium oxide. The gate dielectric layer 112 may have any suitable thickness, such as a thickness of about 0.5-25 nanometers.

The illustrative gate 114 may include at least one p-type work function metal or n-type work function metal, depending on whether the transistor is to be a p-type metal oxide semiconductor (PMOS) or an n-type metal oxide semiconductor (NMOS) transistor. In some implementations, the gate 114 may include a stack of two or more metal layers, where one or more metal layers are work function metal layers and at least one metal layer is a fill metal layer. For a p-MOS transistor, metals that may be used for the gate 114 include, but are not limited to, ruthenium, palladium, platinum, cobalt, nickel, conductive metal oxides (e.g., ruthenium oxide), and any of the metals discussed below with reference to an n-MOS transistor (e.g., for work function tuning). For an n-MOS transistor, metals that may be used for the gate 114 include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a p-MOS transistor (e.g., for work function tuning). The conductive material 120 that is adjacent the gate 114 may be any suitable conductor. In the illustrative embodiment the conductive material 120 is tungsten.

Referring now to FIGS. 5 and 6, in one embodiment, a PMOS GAA FET 500 is shown at cross-sections that correspond to those in FIGS. 2 and 3. Other than the specific differences described below, the components of the PMOS FETs 500 may be similar to or the same as the corresponding components of the NMOS FETs 100, a description of which will not be repeated in the interest of clarity. In the illustrative embodiment, the PMOS FETs 500 and the NMOS FETs 100 are on the same die. Individual complementary metal-oxide-semiconductor (CMOS) logic gates may include one or more NMOS FETs 100 and one or more PMOS FETs 500.

In an illustrative embodiment, the PMOS FET 500 has source/drain contacts 502 that extend into source/drain regions 504. As shown in the figures, the PMOS source/drain contacts 502 do not extend as deeply into the source/drain regions 504 as the NMOS source/drain contacts 106 extend into the source/drain regions 204. In some embodiments, extending the PMOS source/drain contacts 502 further into the source/drain regions 504 may reduce the compressive strain applied by the source/drain regions 504, as described in more detail below. As the compressive strain can increase the speed of the FET 500, the contacts 502 may not extend as far into the source/drain regions 504. The contacts 502 may extend any suitable depth into the source/drain regions 504, such as 5-40 nanometers or deeper. In an illustrative embodiment, the contacts 502 may extend to a depth that is at least as deep as one or more of the nanoribbons 104A-C. For example, the contacts 502 may extend at least as deep as the first nanoribbon 104C, the second nanoribbon 104B, the third nanoribbon 104A, etc. In some embodiments, the contacts 106 may extend deeper into the source/drain regions 204 by one or more nanoribbons 104 compared to how deeply the contacts 502 extend into the source/drain regions 504.

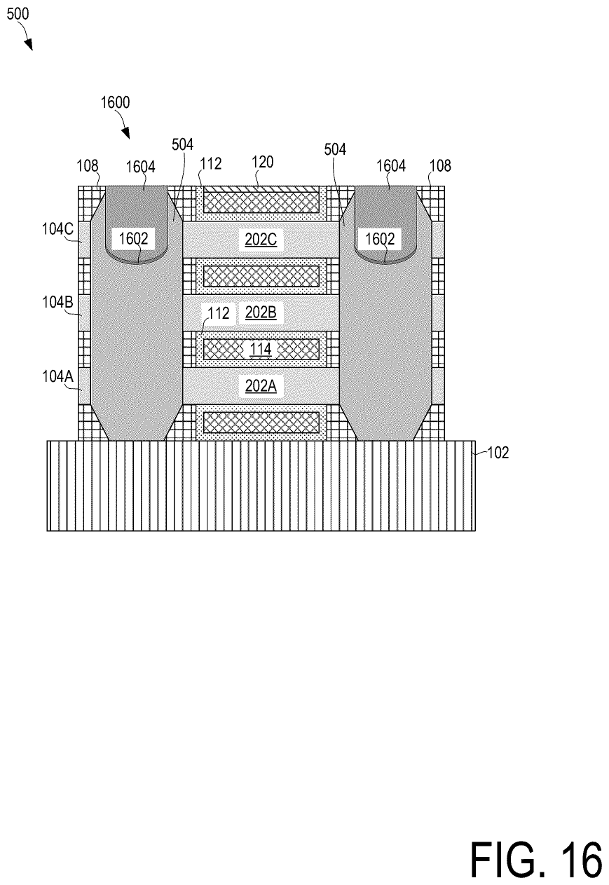

The source/drain contacts 502 may be any suitable material, such as tungsten, cobalt, tungsten nitride, platinum, ruthenium, and/or the like. In some embodiments, the contact 502 may be a multi-layer contact, as discussed below in regard to FIG. 16. The contacts 502 may be connected to one or more redistribution or interconnect layers.

The illustrative source/drain regions 504 are silicon-germanium doped with, e.g., boron. The source/drain regions 504 of silicon-germanium may include any suitable amount of germanium, such as silicon-germanium with 20-60% germanium, by number of atoms. More generally, the source/drain regions 504 may be made of any suitable combination of doped or undoped semiconductors, such a silicon, silicon-germanium, germanium, germanium-tin alloys, germanium-silicon-tin alloys, a III-V semiconductor, a perovskite, a compound semiconductor, etc. The source/drain regions 504 may have any suitable concentration of any suitable dopant, such as a dopant concentration of 10¹⁷-10²³ cm⁻³ of boron, aluminum, indium, gallium, and/or the like.

In an illustrative embodiment, replacing some of the silicon with germanium places the source/drain regions 504 under stress that pushes on the channel regions 202A-C, which puts a compressive strain on the channel regions 202A-C. The channel regions 202A-C of the PMOS FET 500 may be under compression to decrease the lattice constant in the dimension extending from one source/drain region 504 to the other source/drain region 504 by, e.g., 0.5-2%. In an illustrative embodiment, the lattice constant in that dimension may be decreased by about 1.5%. The strain may decrease the lattice constant in the dimension extending from one source/drain region 504 to the other source/drain region 504 to, e.g., 0.5325-0.5404 nanometers. As a result, the lattice constant in the dimension between the source/drain regions 504 of the PMOS FETs 500 may be, e.g., 1-4% smaller than the lattice constant in the dimension between the source/drain regions 204 of the NMOS FETs 100.

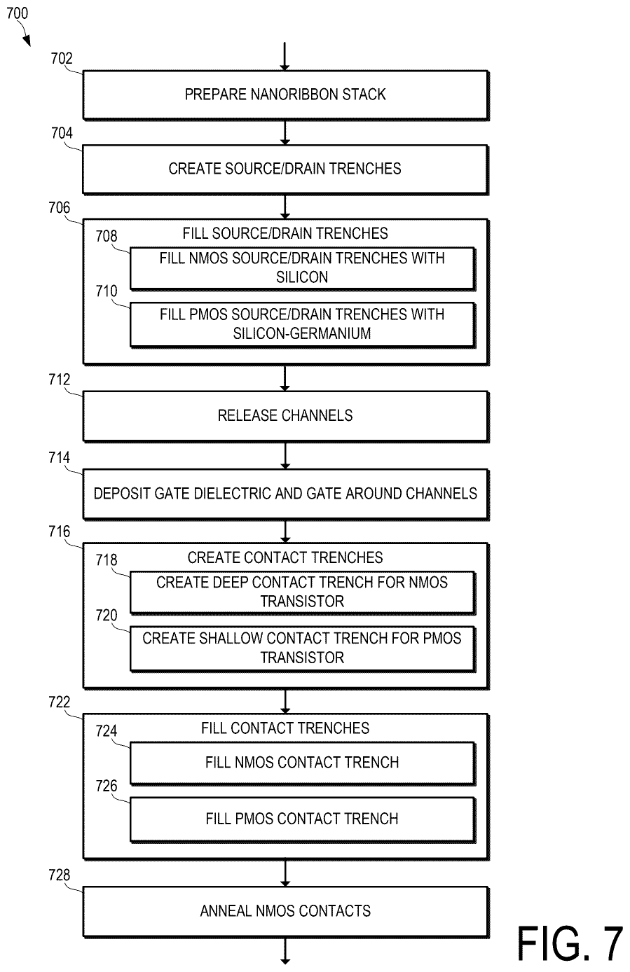

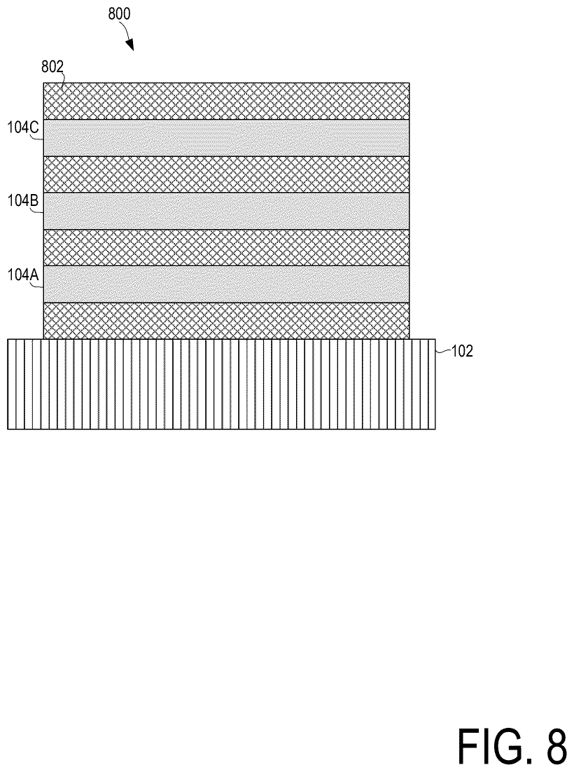

Referring now to FIG. 7, in one embodiment, a flowchart for a method 700 for creating a transistor is shown. The method 700 may be executed by a technician and/or by one or more automated machines. In some embodiments, one or more machines may be programmed to do some or all of the steps of the method 700. Such a machine may include, e.g., a memory, a processor, data storage, etc. The memory and/or data storage may store instructions that, when executed by the machine, causes the machine to perform some or all of the steps of the method 700. The method 700 may use any suitable set of techniques that are used in semiconductor processing, such as chemical vapor deposition, atomic layer deposition, physical vapor deposition, molecular beam epitaxy, pulsed laser deposition, layer transfer, photolithography, ion implantation, dry etching, wet etching, plasma etching, reactive ion etching, ion-assisted chemical vapor etching, thermal treatments, etc. FIGS. 8-14 show various stages of the method 700 from the same perspective as FIG. 2.

The method 700 begins in block 702, in which a stack 800 of semiconductor nanoribbons 104A-C is prepared. In the illustrative embodiment, the stack 800 includes alternating layers of silicon-germanium 802 and silicon nanoribbons 104A-C, as shown in FIG. 6.

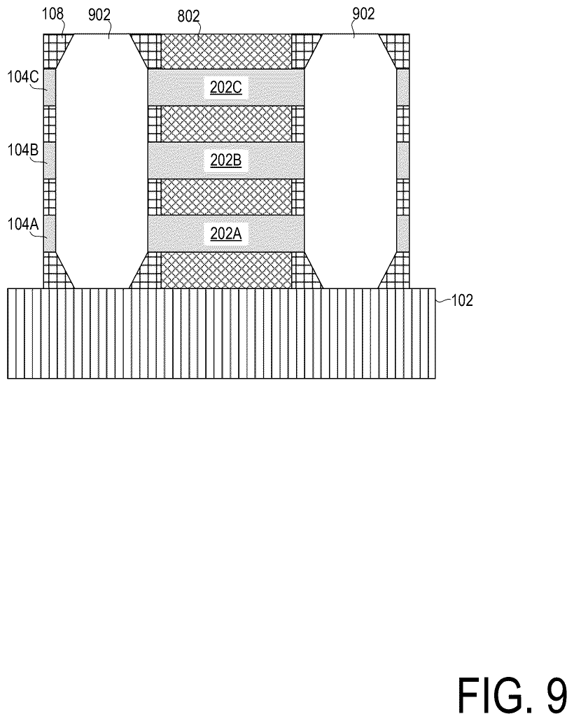

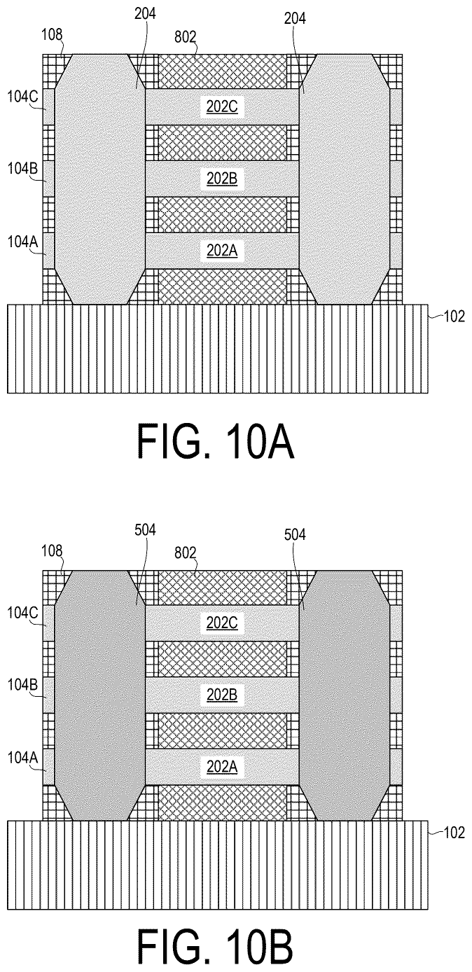

In block 704, trenches 902 for the source/drain regions are created, as shown in FIG. 9. In an illustrative embodiment, the dielectric spacers 108 are disposed around the trenches 902, as shown in the figure. In block 706, the source/drain trenches 902 are filled with source/drain regions. For an NMOS FET 100, in block 708, the source/drain trenches 902 may be filled with silicon, such as phosphorous-doped silicon, as shown in FIG. 10A. For a PMOS FET 500, in block 710, the source/drain trenches 902 may be filled with silicon-germanium, such as boron-doped silicon-germanium, as shown in FIG. 10B.

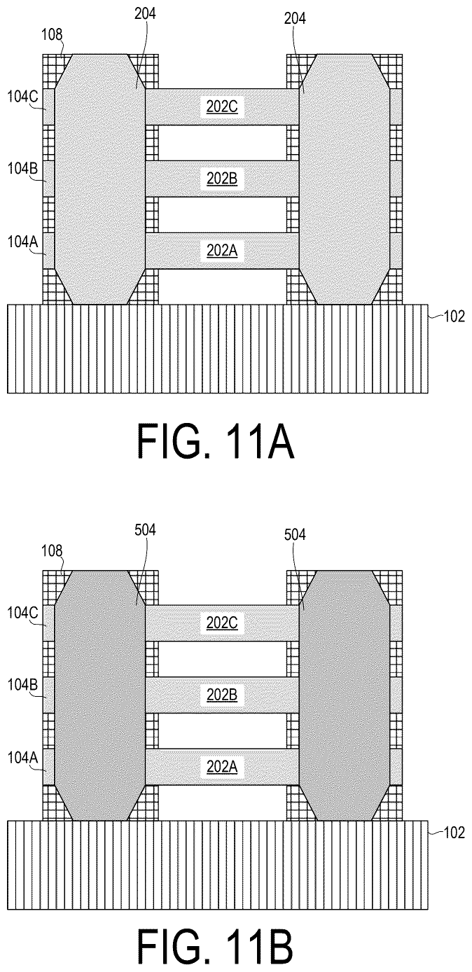

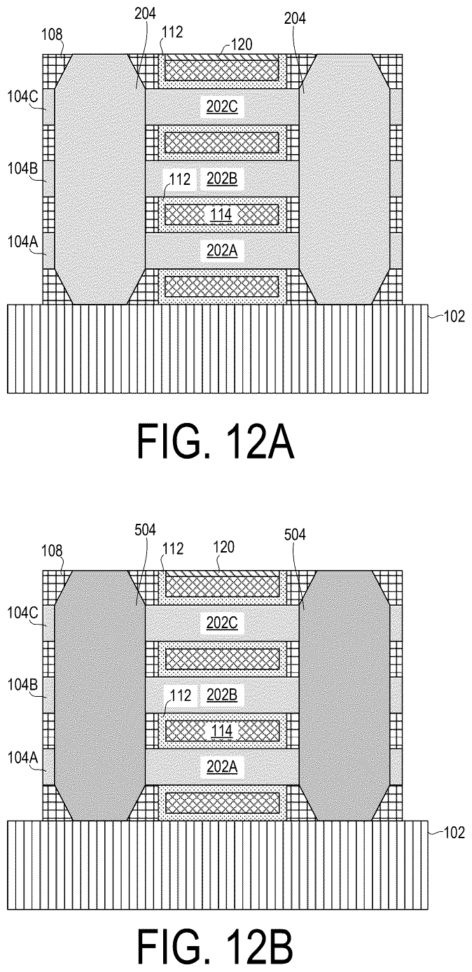

In block 712, the channel regions 202A-C are released by selectively etching the layers of silicon-germanium 802 or other superlattice spacing material, as shown in FIGS. 11A and 11B. In block 714, the gate dielectric layer 112, gate 114, and conductive material 120 are deposited, as shown in FIGS. 12A and 12B.

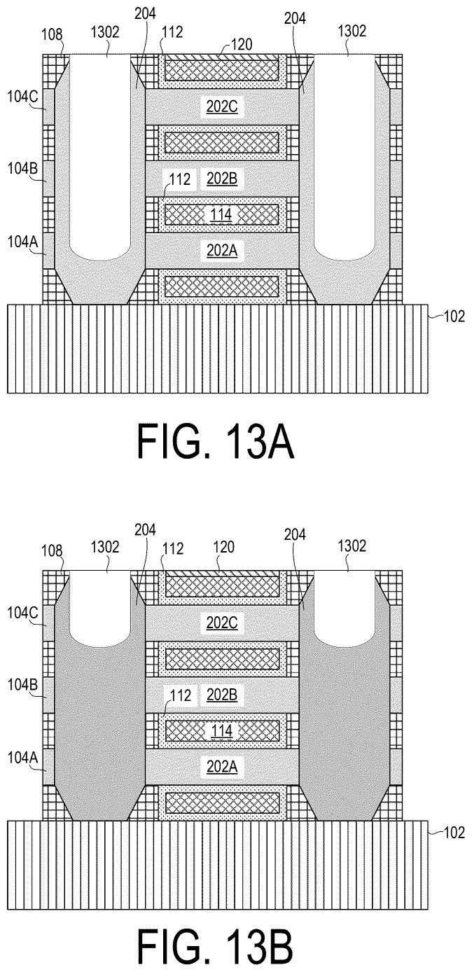

In block 716, source/drain contact trenches 1302 are formed in the source/drain regions. In block 718, deep source/drain contact trenches 1302 are formed for an NMOS FET 100, as shown in FIG. 13A. In block 720, shallow source/drain contact trenches 1302 are formed for a PMOS FET 100, as shown in FIG. 13B.

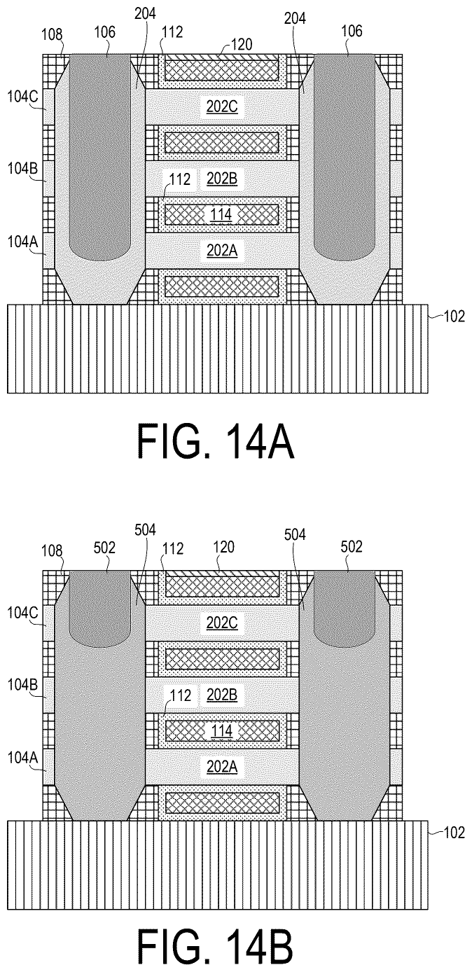

In block 722, the source/drain contact trenches are filled. In block 724, source/drain contact trenches for an NMOS FET 100 are filled with source/drain contacts 106, as shown in FIG. 14A. In block 726, source/drain contact trenches for a PMOS FET 500 are filled with source/drain contacts 502, as shown in FIG. 14B.

In an illustrative embodiment, the source/drain contact trenches are filled with source/drain contacts 106 that have a large number of relatively small grain sizes. For example, the source/drain contacts 106 may initially have a large number of relatively small grains of tungsten, with impurities such as tungsten nitride and tungsten carbide. In another embodiment, the source/drain contacts 106 may initially have a large number of relatively small grains of molybdenum, with impurities such as molybdenum nitride and molybdenum carbide.

In block 728, the NMOS source/drain contacts 106 are annealed. In annealing the NMOS source/drain contacts 106, the grain size of the source/drain contacts 106 may grow, which may reduce the size of the NMOS source/drain contacts 106, pulling in on the surrounding source/drain regions 204 and putting the channel regions 202A-C of the NMOS FET 100 under tensile strain.

It should be appreciated that the NMOS source/drain contacts 106 may be annealed by heating the substrate, including the PMOS FETs 500, up to a temperature of, e.g., 800-1,000°C. However, in an illustrative embodiment, the PMOS source/drain contacts 502 are formed from a material that does not anneal and contract while the NMOS source/drain contacts 106 are being annealed.

Referring now to FIGS. 15 and 16, in some embodiments, the contact 106 and contact 502 may be embodied as multi-layer contact 1500 and multi-layer contact 1600, respectively. The contact 1500 and contact 1600 may include a first layer 1502 and first layer 1602 of titanium, titanium silicide, titanium nitride, or a combination thereof. The first layers 1502, 1602 may be relatively thin. For example, the first layers 1502, 1602 may have a thickness of, e.g., 0.5-10 nanometers. The contact 1500 may include a second layer 1504, which may be similar materials as the contact 106 described above, and the contact 1600 may include a second layer 1604, which may be similar materials as the contact 502 described above. It should be appreciated that the multi-layer contacts 1500, 1600 may be included in any suitable embodiment described herein, as appropriate.

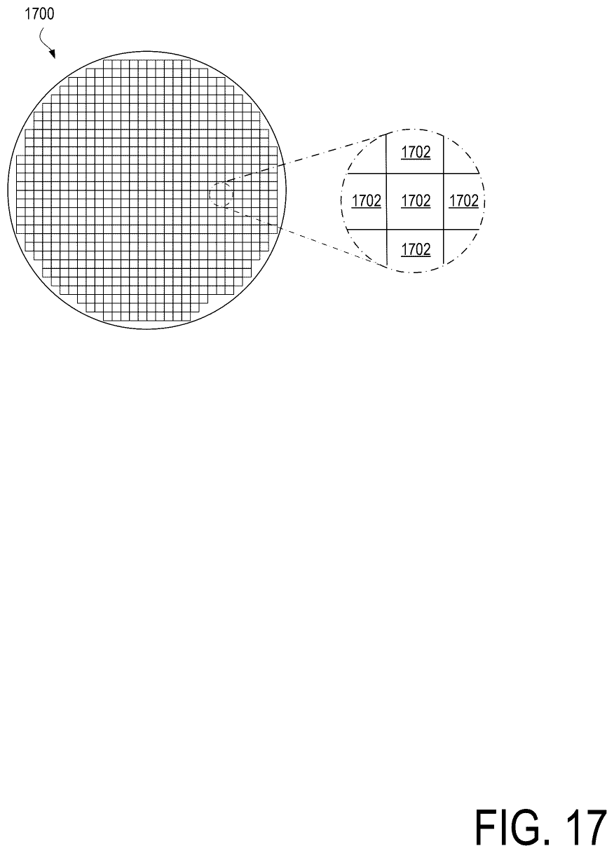

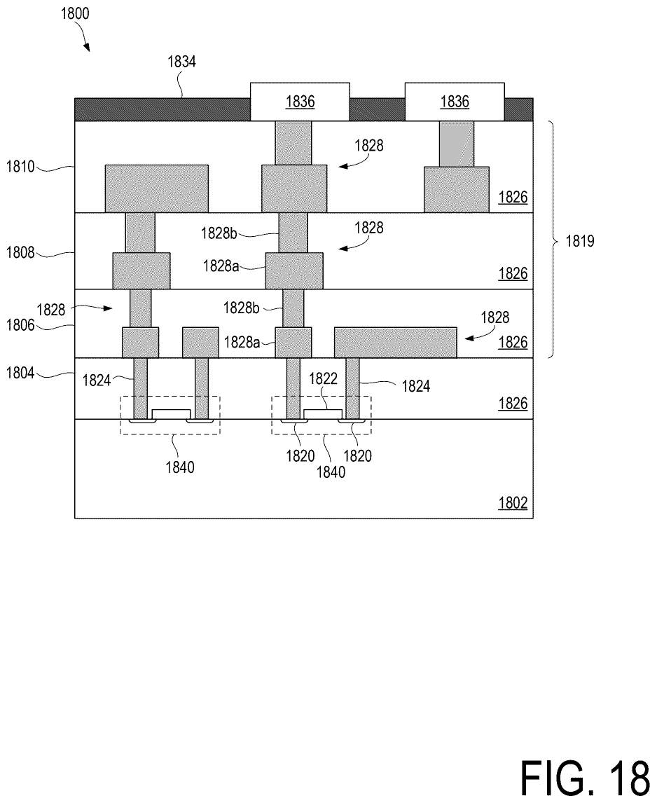

FIG. 17 is a top view of a wafer 1700 and dies 1702 that may be included in any of the microelectronic assemblies disclosed herein (e.g., as any suitable ones of the substrates 102). The wafer 1700 may be composed of semiconductor material and dies 1702 having integrated circuit structures formed on a surface of the wafer 1700. The individual dies 1702 may be a repeating unit of an integrated circuit product that includes any suitable integrated circuit. After the fabrication of the semiconductor product is complete, the wafer 1700 may undergo a singulation process in which the dies 1702 are separated from one another to provide discrete “chips” of the integrated circuit product. The dies 1702 may be any of the substrates 102 or dies disclosed herein. The dies 1702 may include one or more transistors (e.g., transistors 1840 of FIG. 18, discussed below), supporting circuitry to route electrical signals to the transistors, passive components (e.g., signal traces, resistors, capacitors, or inductors), and/or any other integrated circuit components that can be fabricated on the wafer. In some embodiments, the wafer 1700 or the dies 1702 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), logic gates (e.g., AND, OR, NAND, and NOR gates), or any other suitable circuit element. Multiple ones of these devices and components may be combined on a single die. For example, a memory array formed by multiple memory devices may be formed on the same die as a processor unit or other logic configured to store information in the memory devices or execute instructions stored in the memory array. Various ones of the microelectronic assemblies disclosed herein may be manufactured using a die-to-wafer assembly technique in which some substrates 102 are attached to a wafer 1700 that include others of the substrates 102, and the wafer 1700 is subsequently singulated.

FIG. 18 is a cross-sectional view of an integrated circuit structure 1800 that may be included in any of the microelectronic assemblies disclosed herein (e.g., in any of the substrates 102). Multiple instances of the integrated circuit structure 1800 may be included in the dies 1702 (FIG. 17). The integrated circuit structure 1800 may be formed on a die substrate 1802. The die substrate 1802 may be a semiconductor substrate composed of semiconductor material including, for example, n-type or p-type materials (or a combination of both). The die substrate 1802 may include, for example, a crystalline substrate formed using a bulk silicon or a silicon-on-insulator (SOI) substructure. In some embodiments, the die substrate 1802 can comprise a layer of silicon on top of an SOI layer with bulk silicon below the SOI layer. In some embodiments, the die substrate 1802 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1802. Although a few examples of materials from which the die substrate 1802 may be formed are described here, any material that may serve as a foundation for an integrated circuit structure 1800 may be used. The die substrate 1802 may be part of a singulated die (e.g., dies 1702 of FIG. 17) or a wafer (e.g., wafer 1700 of FIG. 17).

The integrated circuit structure 1800 may include device layer 1804 disposed on the die substrate 1802. The device layer 1804 may include features of transistors 1840 (e.g., metal oxide semiconductor field-effect transistors (MOSFETs)) formed on the die substrate 1802. The transistors 1840 may include, for example, source and drain regions (S/D regions 1820), a gate 1822 to control current flow between the S/D regions 1820, and S/D contacts 1824 to route electrical signals to and from the S/D regions 1820. The transistors 1840 may include additional features not depicted for the sake of clarity, such as device isolation regions, gate contacts, and the like. The transistors 1840 are not limited to the type and configuration depicted in FIG. 18 and may include a wide variety of other types and configurations such as, for example, non-planar transistors, or a combination of planar and non-planar transistors. Non-planar transistors may include FinFET transistors, such as double-gate transistors or tri-gate transistors, and wrap-around or all-around gate transistors, such as nanoribbon, nanosheet, or nanowire transistors.

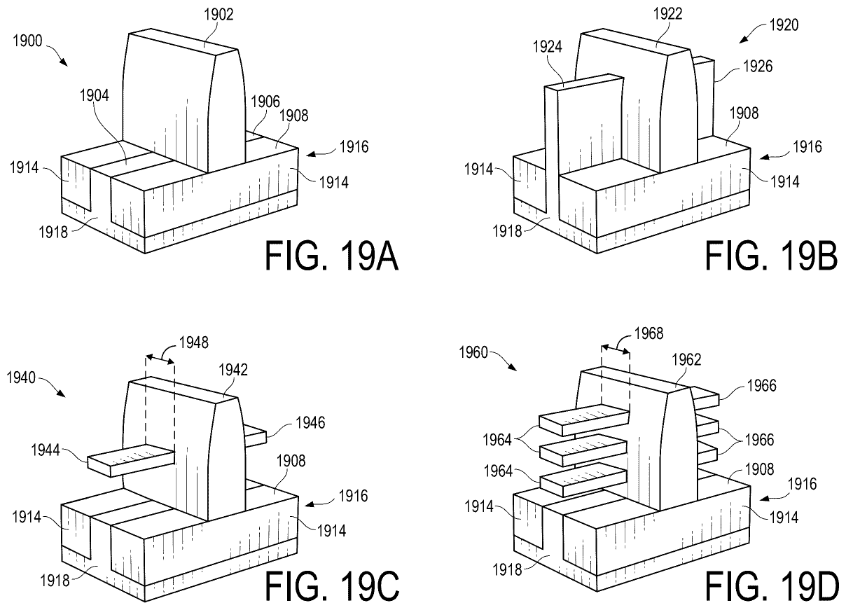

FIGS. 19A-19D are perspective views of example planar, FinFET, gate-all-around, and stacked gate-all-around transistors. The transistors illustrated in FIGS. 19A-19D are formed on a substrate 1916 having a substrate surface 1908 and a bulk region 1918. Isolation regions 1914 separate the source and drain regions of the transistors from other transistors.

FIG. 19A is a perspective view of an example transistor 1900 comprising a gate 1902 that controls current flow between a source region 1904 and a drain region 1906. The transistor 1900 is planar in that the source region 1904, the drain region 1906 and the substrate surface 1908 lie in the same plane.

FIG. 19B is a perspective view of an example transistor 1920 comprising a gate 1922 that controls current flow between a source region 1924 and a drain region 1926. The transistor 1920 is non-planar in that the source region 1924 and the drain region 1926 comprise “fins” that extend upwards from the substrate surface 1908. The transistor 1920 can be referred to as a FinFET. As the gate 1922 encompasses three sides of the fin that extends from the source region 1924 to the drain region 1926, the transistor 1920 can be considered a tri-gate transistor. FIG. 19B illustrates one S/D fin extending through the gate 1922, but multiple S/D fins can extend through the gate of a FinFET transistor.

FIG. 19C is a perspective view of a transistor 1940 comprising a gate 1942 that controls current flow between a source region 1944 and a drain region 1946. The transistor 1940 is non-planar in that the source region 1944 and the drain region 1946 lie in a different plane than the substrate surface 1908. As the gate 1942 encompasses all sides of the channel region of the transistor 1940 that extends from the source region 1944 to the drain region 1946, the transistor 1940 can be referred to as a gate-all-around (GAA) transistor.

FIG. 19D is a perspective view of a transistor 1960 comprising a gate 1962 that controls current flow between multiple elevated source regions 1964 and multiple elevated drain regions 1966. The transistor 1960 is a stacked GAA transistor as the gate controls the flow of current between multiple elevated S/D regions stacked on top of each other. The transistors 1940 and 1960 are considered gate-all-around transistors as the gates encompass all sides of the channel regions of the transistor that extends from the source regions to the drain regions. The transistors 1940 and 1960 can alternatively be referred to as nanowire, nanosheet, or nanoribbon transistors depending on the width (e.g., widths 1948 and 1968 of transistors 1940 and 1960, respectively) of the channel regions extending through the gate.

Returning to FIG. 18, transistors 1840 may include a gate 1822 formed of at least two layers, a gate dielectric, and a gate electrode. The gate dielectric may include one or more layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For PMOS transistors, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For NMOS transistors, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, such as in the FinFET illustrated in FIG. 19B, the gate electrode may have an upside-down U-shape that includes a top portion substantially parallel to the surface of the die substrate 1802 and two side portions that are substantially perpendicular to the top surface of the die substrate 1802. In other embodiments, such as the planar FET illustrated in FIG. 19A, at least one of the metal layers that form the gate electrode may be a planar layer that is substantially parallel to the top surface of the die substrate 1802 without side portions. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack (comprising the gate dielectric and the gate electrode) to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of sidewall spacer pairs may be used; for instance, two pairs, three pairs, or four pairs of sidewall spacers may be formed on opposing sides of the gate stack.

The S/D regions 1820 may be formed within the die substrate 1802 adjacent to the gate 1822 of transistors 1840. The S/D regions 1820 may be formed using an implantation/diffusion process or an etching/deposition process, for example. In the former process, dopants such as boron, aluminum, antimony, phosphorous, or arsenic may be ion-implanted into the die substrate 1802 to form the S/D regions 1820. An annealing process that activates the dopants and causes them to diffuse further into the die substrate 1802 may follow the ion implantation process. In the latter process, the die substrate 1802 may first be etched to form recesses at the locations of the S/D regions 1820. An epitaxial deposition process may then be carried out to fill the recesses with material that is used to fabricate the S/D regions 1820. In some implementations, the S/D regions 1820 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1820 may be formed using one or more alternate semiconductor materials such as germanium or a group III-V material or alloy. In further embodiments, one or more layers of metal and/or metal alloys may be used to form the S/D regions 1820.

Electrical signals, such as power and/or information-carrying signals (e.g., input/output (I/O) signals, may be routed to and/or from devices (e.g., transistors 1840) of the device layer 1804 through one or more interconnect layers disposed on the device layer 1804 (illustrated in FIG. 18 as interconnect layers 1806-1810). For example, electrically conductive features of the device layer 1804 (e.g., the gate 1822 and the S/D contacts 1824) may be electrically coupled with interconnect structures 1828 of the interconnect layers 1806-1810. The one or more interconnect layers 1806-1810 may form a metallization stack 1819 (which can also be referred to as an “ILD stack” (inter-layer dielectric stack)) of the integrated circuit structure 1800.

The interconnect structures 1828 may be arranged within the interconnect layers 1806-1810 to route electrical signals according to a wide variety of designs; in particular, the arrangement is not limited to the particular configuration of interconnect structures 1828 depicted in FIG. 18. Although a particular number of interconnect layers 1806-1810 is depicted in FIG. 18, embodiments of the present disclosure include integrated circuit structures having more or fewer interconnect layers than depicted.

In some embodiments, the interconnect structures 1828 may include traces or lines 1828a and/or vias 1828b filled with an electrically conductive material such as a metal. The lines 1828a may be arranged to route electrical signals in a direction of a plane that is substantially parallel with a surface of the die substrate 1802 upon which the device layer 1804 is formed. For example, the lines 1828a may route electrical signals in a direction in and out of the page and/or in a direction across the page from the perspective of FIG. 18. The vias 1828b may be arranged to route electrical signals in a direction of a plane that is substantially perpendicular to the surface of the die substrate 1802 upon which the device layer 1804 is formed. In some embodiments, lines 1828a of different interconnect layers 1806-1810 are electrically coupled by vias 1828b.

The interconnect layers 1806-1810 may include a dielectric material 1826 within which the interconnect structures 1828 are disposed, as shown in FIG. 18. In some embodiments, dielectric material 1826 in different ones of the interconnect layers 1806-1810 may have different compositions; in other embodiments, the composition of the dielectric material 1826 between different interconnect layers 1806-1810 may be the same. The device layer 1804 may include a dielectric material 1826 within which the transistors 1840 are disposed and upon which a bottom layer of the metallization stack is located. The dielectric material 1826 that is part of the device layer 1804 may have a different composition than the dielectric material 1826 included in the interconnect layers 1806-1810; in other embodiments, the composition of the dielectric material 1826 in the device layer 1804 may be the same as a dielectric material 1826 included in any one of the interconnect layers 1806-1810.

A first interconnect layer 1806 (which can be referred to as a Metal 1 or “M1” layer) may be formed directly on the device layer 1804. In some embodiments, the first interconnect layer 1806 may include lines 1828a and/or vias 1828b, as shown. The lines 1828a of the first interconnect layer 1806 may be coupled with contacts (e.g., the S/D contacts 1824) of the device layer 1804. The vias 1828b of the first interconnect layer 1806 may be coupled with the lines 1828a of a second interconnect layer 1808.

The second interconnect layer 1808 (which can be referred to as a Metal 2 or “M2” layer) may be formed directly on the first interconnect layer 1806. In some embodiments, the second interconnect layer 1808 may include vias 1828b to couple the lines 1828a of the second interconnect layer 1808 with the lines 1828a of a third interconnect layer 1810. Although the lines 1828a and the vias 1828b are structurally delineated with a line within individual interconnect layers for the sake of clarity, the lines 1828a and the vias 1828b may be structurally and/or materially contiguous (e.g., simultaneously filled during a dual-damascene process) in some embodiments.

The third interconnect layer 1810 (which can be referred to as a Metal 3 or “M3” layer) (and additional interconnect layers, as desired) may be formed in succession on the second interconnect layer 1808 according to similar techniques and configurations described in connection with the second interconnect layer 1808 or the first interconnect layer 1806. In some embodiments, the interconnect layers that are “higher up” in the metallization stack 1819 in the integrated circuit structure 1800 (i.e., farther away from the device layer 1804) may be thicker than the interconnect layers that are lower in the metallization stack 1819, with lines 1828a and vias 1828b in the higher interconnect layers being thicker than those in the lower interconnect layers.

The integrated circuit structure 1800 may include a solder resist material 1834 (e.g., polyimide or similar material) and conductive contacts 1836 formed on the stack of interconnect layers 1806-1810. In FIG. 18, the conductive contacts 1836 are illustrated as taking the form of bond pads. The conductive contacts 1836 may be electrically coupled with interconnect structures 1828 of the top-most layer in the metallization stack 1819 and configured to route electrical signals between the transistors 1840 and components external to the integrated circuit structure 1800. For example, solder bonds may be formed on the conductive contacts 1836 to mechanically and/or electrically couple an integrated circuit component comprising the integrated circuit structure 1800 with another component (e.g., a printed circuit board). The integrated circuit structure 1800 may include additional or alternate structures to route electrical signals from the interconnect layers 1806-1810; for example, the conductive contacts 1836 may include other analogous features (e.g., posts) that can route the electrical signals between the transistors 1840 and external components.

In some embodiments in which the integrated circuit structure 1800 is part of a double-sided die (e.g., like the substrate 102), the integrated circuit structure 1800 may include a second metallization stack (not shown) located on the opposite side of the die substrate 1802 from the device layer 1804. This second metallization stack may include multiple interconnect layers as discussed above with reference to the interconnect layers 1806-1810. Through-silicon vias (TSVs) that extend through the die substrate 1802 can provide electrically conductive pathways from the transistors 1840 to the second metallization stack and the second metallizaton stack can electrically couple the TSVs to additional conductive contacts (not shown) located on the opposite side of the integrated circuit structure 1800 from the conductive contacts 1836.

In some embodiments, TSVs extending through the die substrate 1802 can be used for routing power and ground signals from conductive contacts located on the opposite side of the integrated circuit structure 1800 from the conductive contacts 1836 to the transistors 1840 and any other components integrated into the integrated circuit structure 1800, and the metallization stack 1819 can be used to route information-carrying signals from the conductive contacts 1836 to transistors 1840 and any other components integrated into the integrated circuit structure 1800. Put another way, the routing of power and ground signals to the transistors 1840 can be separated (via a back-side or bottom-side metallizaton stack and TSVs) from the routing of information-carrying signals to the transistors. The power and ground signals are provided by a back-side or bottom-side metallization stack and TSVs, and information-carrying signals are provide by a top-side metallization stack (e.g., metallization stack 1819).

Several integrated circuit dies may be stacked with one or more TSVs in the individual stacked dies providing connection between one of the dies to any of the other dies in the stack. For example, one or more high-bandwidth memory (HBM) integrated circuit dies can be stacked on top of a base integrated circuit die and TSVs in the HBM dies can provide connection between the individual HBM dies and the base integrated circuit die. Conductive contacts can provide additional connections between adjacent integrated circuit dies in the stack. In some embodiments, the conductive contacts can be fine-pitch solder bumps (microbumps).

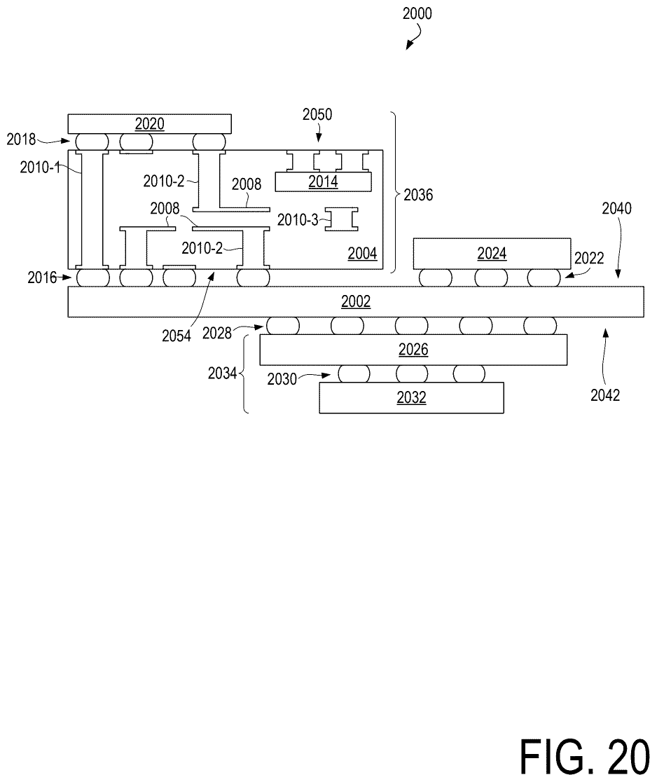

FIG. 20 is a cross-sectional view of an integrated circuit device assembly 2000 that may include any of the microelectronic assemblies disclosed herein. In some embodiments, the integrated circuit device assembly 2000 may include any of the GAA FETs 100 and/or GAA FETs 500. The integrated circuit device assembly 2000 includes a number of components disposed on a circuit board 2002 (which may be a motherboard, system board, mainboard, etc.). The integrated circuit device assembly 2000 includes components disposed on a first face 2040 of the circuit board 2002 and a second face 2042 of the circuit board 2002, the second face 2042 opposing the first face 2040. Generally, components may be disposed on either or both of the first face 2040 and the second face 2042 of the circuit board 2002. Any of the integrated circuit components discussed below with reference to the integrated circuit device assembly 2000 may include any suitable ones of the embodiments of the GAA FETs 100 disclosed herein.

In some embodiments, the circuit board 2002 may be a printed circuit board (PCB) including multiple metal (or interconnect) layers separated from one another by layers of dielectric material and interconnected by electrically conductive vias. The individual metal layers comprise conductive traces. The metal layers may be formed in a desired pattern to route electrical signals between the components electrically coupled to the circuit board 2002. In other embodiments, the circuit board 2002 may be a non-PCB substrate.

The integrated circuit device assembly 2000 illustrated in FIG. 20 includes a package-on-interposer structure 2036 coupled to the first face 2040 of the circuit board 2002 by coupling components 2016. The coupling components 2016 may electrically and mechanically couple the package-on-interposer structure 2036 to the circuit board 2002 and may include solder balls (as shown in FIG. 20), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. (Thus, a coupling component may comprise a conductive contact.) The coupling components 2016 may serve as the coupling components illustrated or described for any substrate assembly or substrate assembly components described herein (e.g., integrated circuit components), as appropriate.

The package-on-interposer structure 2036 may include an integrated circuit component 2020 coupled to an interposer 2004. The interposer 2004 may provide an intervening substrate used to bridge the circuit board 2002 and the integrated circuit component 2020. The integrated circuit component 2020 is coupled to the interposer 2004 by coupling components 2018. The coupling components 2018 may take any suitable form, such as the forms discussed above with reference to the coupling components 2016. Although FIG. 20 shows just one integrated circuit component attached to the interposer, multiple integrated circuit components may be coupled to the interposer 2004. Additional interposers may be coupled to the interposer 2004.

The integrated circuit component 2020 may be a packaged or unpacked integrated circuit product that includes one or more integrated circuit dies (e.g., the die 1702 of FIG. 17, a die comprising the integrated circuit structure 1800 of FIG. 18) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one unpackaged example of an integrated circuit component 2020, a single monolithic integrated circuit die comprises solder bumps attached to contacts on the die. The solder bumps allow the die to be directly attached to the interposer 2004. The integrated circuit component 2020 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 2020 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 2020 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 2020 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 2004 may spread connections to a wider or narrower pitch or reroute a connection to a different connection. For example, the interposer 2004 may couple coupling components 2018 having a first pitch to coupling components 2016 having a wider pitch than the first pitch. In the embodiment illustrated in FIG. 20, the integrated circuit component 2020 and the circuit board 2002 are attached to opposing sides of the interposer 2004. In other embodiments, the integrated circuit component 2020 and the circuit board 2002 may be attached to a same side of the interposer 2004. In some embodiments, three or more components may be interconnected by way of the interposer 2004.

In some embodiments, the interposer 2004 may be formed as a PCB, including multiple metal layers separated from one another by layers of dielectric material and interconnected by electrically conductive vias. In some embodiments, the interposer 2004 may be formed of an epoxy resin, a fiberglass-reinforced epoxy resin, an epoxy resin with inorganic fillers, a ceramic material, or a polymer material such as polyimide. In some embodiments, the interposer 2004 may be formed of alternate rigid or flexible materials that may include the same materials described above for use in a semiconductor substrate, such as silicon, germanium, and other group III-V and group IV materials. The interposer 2004 may include metal interconnects 2008 and vias, including but not limited to through hole vias 2010-1 (that extend from a first face 2050 of the interposer 2004 to a second face 2054 of the interposer 2004), blind vias 2010-2 (that extend from the first face 2050 or the second face 2054 of the interposer 2004 to an internal metal layer), and buried vias 2010-3 (that connect internal metal layers).

In some embodiments, the interposer 2004 can comprise a silicon interposer. Through silicon vias (TSV) extending through the silicon interposer can connect connections on a first face of a silicon interposer to an opposing second face of the silicon interposer. In some embodiments, an interposer 2004 comprising a silicon interposer can further comprise one or more routing layers to route connections on a first face of the interposer 2004 to an opposing second face of the interposer 2004.

In some embodiments the interposer 2004, as well as the circuit board 2002, can comprise an amorphous solid layer of glass (which can be referred to a glass core or glass substrate). In some embodiments, the layer of glass can comprise silica (comprising silicon dioxide (SiO₂)), fused silica, aluminosilicate (comprising aluminum oxide (Al₂O₃) and silicon dioxide), borosilicate (comprising silicon dioxide and boron trioxide (B₂O₃)), or alumino-borosilicate (comprising aluminum oxide, silicon dioxide, and boron trioxide). In some embodiments, the layer of glass can comprise one or more of the following additives: aluminum oxide, boron trioxide, magnesium oxide (MgO), calcium oxide (CaO), strontium oxide (SrO), barium oxide (BaO), tin(IV) oxide (SnO₂), nitrous oxide (Na₂O), potassium oxide (K₂O), diphosphorous trioxide (P₂O₃), zirconium dioxide (ZrO₂), lithium oxide (Li₂O), titanium, and zinc. In some embodiments, the layer of glass can comprise silicon and oxygen, as well as one or more of aluminum, boron, magnesium, calcium, barium, tin, sodium, potassium, strontium, phosphorous, zirconium, lithium, titanium, and zinc. In some embodiments, the layer of glass comprises at least 23 percent silicon by weight, at least 26 percent oxygen by weight, and at least five percent aluminum by weight. In some embodiments, the layer of glass does not include an organic adhesive or an organic material. For example, the layer of glass is not a substrate or a board comprising glass fibers and an epoxy binder, such as a printed circuit board (PCB) comprising multiple metal (or interconnect) layers separated from one another by layers of dielectric material (e.g., FR-4 or other fiberglass-reinforced epoxy laminate) and interconnected by electrically conductive vias.

In some embodiments, the glass layer has a thickness in the range of about 50 microns to about 1.4 millimeters. In some embodiments, the glass layer is or is part of a multi-layer glass substrate (a coreless substrate). Individual glass layers in a multi-layer glass substrate can have a thickness in the range of about 25 microns to about 50 microns. In some embodiments, a glass layer can have a length in the range of about 10 millimeters to about 250 millimeters on a side (e.g., can have an area in the range of about 10 mm×10 mm to about 250 mm×250 mm). In some embodiments, the glass layer comprises a rectangular prism volume with sections or portions (e.g., through-glass vias) removed and filled with other metals (e.g., metal).

In some embodiments, redistribution layers (RDL) can be located on either or both sides of the glass layer to provide electrically conductive paths from top and/or bottom surfaces of the interposer 2004 or circuit board 2002 to the glass layer. The glass layer can comprise through-glass vias (TGVs) that extend through the glass layer to provide electrically conductive paths through the glass core, glass substrate, or glass layer.

The interposer 2004 may further include embedded devices 2014, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 2004. The package-on-interposer structure 2036 may take the form of any of the package-on-interposer structures known in the art.

The integrated circuit device assembly 2000 may include an integrated circuit component 2024 coupled to the first face 2040 of the circuit board 2002 by coupling components 2022. The coupling components 2022 may take the form of any of the embodiments discussed above with reference to the coupling components 2016, and the integrated circuit component 2024 may take the form of any of the embodiments discussed above with reference to the integrated circuit component 2020.

The integrated circuit device assembly 2000 illustrated in FIG. 20 further includes a package-on-package structure 2034 coupled to the second face 2042 of the circuit board 2002 by coupling components 2028. The package-on-package structure 2034 may include an integrated circuit component 2026 and an integrated circuit component 2032 coupled together by coupling components 2030 such that the integrated circuit component 2026 is disposed between the circuit board 2002 and the integrated circuit component 2032. The coupling components 2028 and 2030 may take the form of any of the embodiments of the coupling components 2016 discussed above, and the integrated circuit components 2026 and 2032 may take the form of any of the embodiments of the integrated circuit component 2020 discussed above. The package-on-package structure 2034 may be configured in accordance with any of the package-on-package structures known in the art.

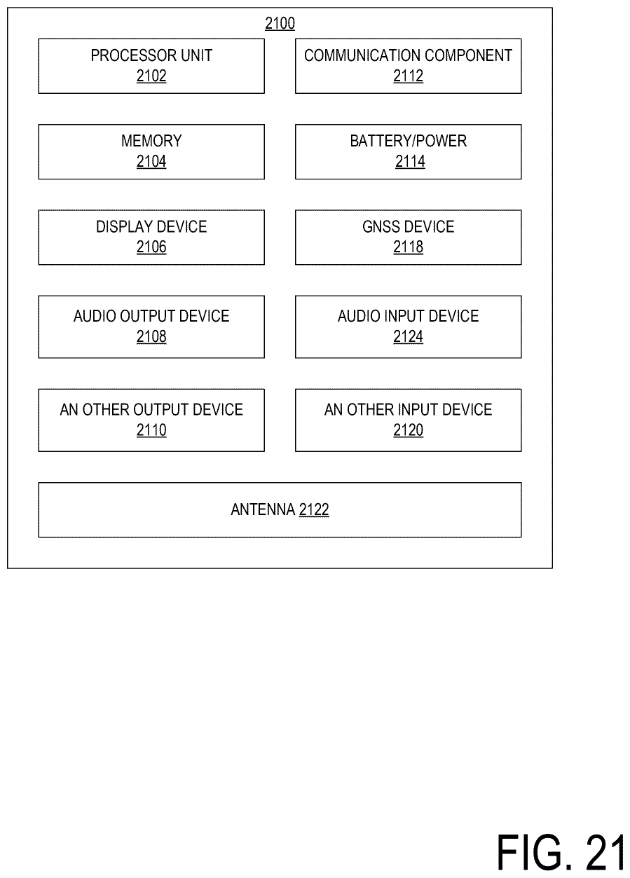

FIG. 21 is a block diagram of an example electrical device 2100 that may include any of the microelectronic assemblies disclosed herein. For example, any suitable ones of the components of the electrical device 2100 may include one or more of the integrated circuit device assembly 2000, integrated circuit component 2020, or integrated circuit structure 1800, integrated circuit dies 1702 disclosed herein, and may be arranged in any of the microelectronic assemblies disclosed herein. A number of components are illustrated in FIG. 21 as included in the electrical device 2100, but any one or more of these components may be omitted or duplicated, as suitable for the application. In some embodiments, some or all of the components included in the electrical device 2100 may be attached to one or more motherboards mainboards, or system boards. In some embodiments, one or more of these components are fabricated onto a single system-on-a-chip (SoC) die.

Additionally, in various embodiments, the electrical device 2100 may not include one or more of the components illustrated in FIG. 21, but the electrical device 2100 may include interface circuitry for coupling to the one or more components. For example, the electrical device 2100 may not include a display device 2106, but may include display device interface circuitry (e.g., a connector and driver circuitry) to which a display device 2106 may be coupled. In another set of examples, the electrical device 2100 may not include an audio input device 2124 or an audio output device 2108, but may include audio input or output device interface circuitry (e.g., connectors and supporting circuitry) to which an audio input device 2124 or audio output device 2108 may be coupled.

The electrical device 2100 may include one or more processor units 2102. As used herein, the terms “processor unit,” “processing unit,” or “processor” may refer to any device or portion of a device that processes electronic data from registers and/or memory to transform that electronic data into other electronic data that may be stored in registers and/or memory. The one or more processor units 2102 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 2100 may include a memory 2104, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 2104 may include memory that is located on the same integrated circuit die as the one or more processor units 2102. This memory may be used as cache memory (e.g., Level 1 (L1), Level 2 (L2 ), Level 3 (L3 ), Level 4 (L4 ), Last Level Cache (LLC)) and may include embedded dynamic random-access memory (eDRAM) or spin transfer torque magnetic random-access memory (STT-MRAM).

In some embodiments of the electrical device 2100, a first one of the one or more processor units 2102 can be heterogeneous or asymmetric to a second one of the one or more processor units 2102 in the electrical device 2100. There can be a variety of differences between the one or more processor units 2102 in a system in terms of a spectrum of metrics of merit including architectural, microarchitectural, thermal, power consumption characteristics, and the like. These differences can effectively manifest themselves as asymmetry and heterogeneity among the one or more processor units 2102 in the electrical device 2100.

In some embodiments, the electrical device 2100 may include a communication component 2112. For example, the communication component 2112 can manage wireless communications for the transfer of data to and from the electrical device 2100. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 2112 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 2112 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 2112 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 2112 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 2112 may operate in accordance with other wireless protocols in other embodiments. The electrical device 2100 may include an antenna 2122 to facilitate wireless communications and/or to receive other wireless communications (such as AM or FM radio transmissions).

In some embodiments, the communication component 2112 may manage wired communications, such as electrical, optical, or any other suitable communication protocols (e.g., IEEE 802.3 Ethernet standards). In some embodiments, the electrical device 2100 comprises multiple communication components. For instance, a first communication component may be dedicated to shorter-range wireless communications such as Wi-Fi or Bluetooth, and a second communication component may be dedicated to longer-range wireless communications such as global positioning system (GPS), EDGE, GPRS, CDMA, WiMAX, LTE, EV-DO, or others. In some embodiments, a first communication component may be dedicated to wireless communications, and a second communication component may be dedicated to wired communications.

The electrical device 2100 may include battery/power circuitry 2114. The battery/power circuitry 2114 may include one or more energy storage devices (e.g., batteries or capacitors) and/or circuitry for coupling components of the electrical device 2100 to an energy source separate from the electrical device 2100 (e.g., AC line power).

The electrical device 2100 may include a display device 2106 (or corresponding interface circuitry, as discussed above). The display device 2106 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 2100 may include an audio output device 2108 (or corresponding interface circuitry, as discussed above). The audio output device 2108 may include any embedded or wired or wirelessly connected external device that generates an audible indicator, such as speakers, headsets, or earbuds.

The electrical device 2100 may include an audio input device 2124 (or corresponding interface circuitry, as discussed above). The audio input device 2124 may include any embedded or wired or wirelessly connected device that generates a signal representative of a sound, such as microphones, microphone arrays, or digital instruments (e.g., instruments having a musical instrument digital interface (MIDI) output). The electrical device 2100 may include a Global Navigation Satellite System device (GNSS) (or corresponding interface circuitry, as discussed above), such as a Global Positioning System (GPS) device. The GNSS device 2118 may be in communication with a satellite-based system and may determine a geolocation of the electrical device 2100 based on information received from one or more GNSS satellites, as known in the art.

The electrical device 2100 may include another output device 2110 (or corresponding interface circuitry, as discussed above). Examples of the other output device 2110 may include an audio codec, a video codec, a printer, a wired or wireless transmitter for providing information to other devices, or an additional storage device.

The electrical device 2100 may include another input device 2120 (or corresponding interface circuitry, as discussed above). Examples of the other input device 2120 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 2100 may have any form factor, such as a hand-held or mobile electrical device (e.g., a cell phone, a smartphone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console), a desktop electrical device, a server, a rack-level computing solution (e.g., blade, tray, or sled computing system), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 2100 may be any other electronic device that processes data. In some embodiments, the electrical device 2100 may comprise multiple discrete physical components. Given the range of devices that the electrical device 2100 can be manifested as in various embodiments, in some embodiments, the electrical device 2100 can be referred to as a computing device or a computing system.

### EXAMPLES

Illustrative examples of the technologies disclosed herein are provided below. An embodiment of the technologies may include any one or more, and any combination of, the examples described below.

Example 1 includes a device comprising a die comprising an NMOS gate-all-around (GAA) transistor comprising a first source or drain region; and a first source or drain contact, the first source or drain contact adjacent the first source or drain region; and a PMOS GAA transistor comprising a second source or drain region; and a second source or drain contact, the second source or drain contact adjacent the second source or drain region, wherein the first source or drain contact extends a first depth into the first source or drain region, wherein the second source or drain contact extends a second depth into the second source or drain region, wherein the first depth is at least 10 nanometers deeper than the second depth.

Example 2 includes the subject matter of Example 1, and wherein the NMOS GAA transistor further comprises a first channel region, the first channel region adjacent the first source or drain region, wherein the PMOS GAA transistor further comprises a second channel region, the second channel region adjacent the second source or drain region, wherein the first channel region has a first lattice constant, wherein the second channel region has a second lattice constant, wherein the second lattice constant is at least 1% greater than the first lattice constant.

Example 3 includes the subject matter of any of Examples 1 and 2, and wherein the first source or drain contact comprises nitrogen and carbon, wherein the second source or drain contact comprises tungsten, cobalt, titanium, platinum, or ruthenium.

Example 4 includes the subject matter of any of Examples 1-3, and wherein the first source or drain contact comprises tungsten.

Example 5 includes the subject matter of any of Examples 1-4, and wherein the first source or drain contact comprises molybdenum.

Example 6 includes the subject matter of any of Examples 1-5, and wherein the first source or drain region comprises silicon and phosphorous, wherein the second source or drain region comprises silicon, germanium, and boron.

Example 7 includes the subject matter of any of Examples 1-6, and wherein the NMOS GAA transistor comprises a first plurality of nanoribbon channels, wherein the first source or drain contact extends deeper than a second nanoribbon channel of the first plurality of nanoribbon channels, wherein the PMOS GAA transistor comprises a second plurality of nanoribbon channels, wherein the second source or drain contact does not extend deeper than a second nanoribbon channel of the second plurality of nanoribbon channels.

Example 8 includes the subject matter of any of Examples 1-7, and further including a processor, wherein the processor comprises the die.

Example 9 includes the subject matter of any of Examples 1-8, and further including one or more memory devices communicatively coupled to the processor.

Example 10 includes a device comprising a die comprising an NMOS gate-all-around (GAA) transistor comprising a first source or drain region; a second source or drain region; and a first channel region, wherein the first channel region is adjacent the first source or drain region and the second source or drain region; and a PMOS GAA transistor comprising a third source or drain region; a fourth source or drain region; and a second channel region, wherein the second channel region is adjacent the third source or drain region and the fourth source or drain region, wherein the first channel region has a first lattice constant, wherein the second channel region has a second lattice constant, wherein the second lattice constant is at least 1% greater than the first lattice constant.

Example 11 includes the subject matter of Example 10, and wherein the NMOS GAA transistor further comprises a first source or drain contact, the first source or drain contact adjacent the first source or drain region, wherein the PMOS GAA transistor further comprises a second source or drain contact, the second source or drain contact adjacent the third source or drain region, wherein the first source or drain contact extends a first depth into the first source or drain region, wherein the second source or drain contact extends a second depth into the third source or drain region, wherein the first depth is at least 10 nanometers deeper than the second depth.

Example 12 includes the subject matter of any of Examples 10 and 11, and wherein the first source or drain contact comprises nitrogen and carbon, wherein the second source or drain contact comprises tungsten, cobalt, titanium, platinum, or ruthenium.

Example 13 includes the subject matter of any of Examples 10-12, and wherein the first source or drain contact comprises tungsten.

Example 14 includes the subject matter of any of Examples 10-13, and wherein the first source or drain contact comprises molybdenum.

Example 15 includes the subject matter of any of Examples 10-14, and wherein the NMOS GAA transistor comprises a first plurality of nanoribbon channels, wherein the first source or drain contact extends deeper than a second nanoribbon channel of the first plurality of nanoribbon channels, wherein the PMOS GAA transistor comprises a second plurality of nanoribbon channels, wherein the second source or drain contact does not extend deeper than a second nanoribbon channel of the second plurality of nanoribbon channels.

Example 16 includes the subject matter of any of Examples 10-15, and wherein the first source or drain region comprises silicon and phosphorous, wherein the second source or drain region comprises silicon, germanium, and boron.

Example 17 includes the subject matter of any of Examples 10-16, and further including a processor, wherein the processor comprises the die.

Example 18 includes the subject matter of any of Examples 10-17, and further including one or more memory devices communicatively coupled to the processor.

Example 19 includes a device comprising a die comprising an NMOS gate-all-around (GAA) transistor comprising a first channel region; a PMOS GAA transistor comprising a second channel region; means for applying a tensile strain on the first channel region; and means for applying a compressive strain on the second channel region.

Example 20 includes the subject matter of Example 19, and wherein the first channel region has a first lattice constant, wherein the second channel region has a second lattice constant, wherein the second lattice constant is at least 1% greater than the first lattice constant.

Example 21 includes the subject matter of any of Examples 19 and 20, and wherein the NMOS GAA transistor further comprises a first source or drain region and a first source or drain contact, the first source or drain contact adjacent the first source or drain region, wherein the PMOS GAA transistor further comprises a second source or drain region and a second source or drain contact, the second source or drain contact adjacent the second source or drain region, wherein the first source or drain contact extends a first depth into the first source or drain region, wherein the second source or drain contact extends a second depth into the second source or drain region, wherein the first depth is at least 10 nanometers deeper than the second depth.

Example 22 includes the subject matter of any of Examples 19-21, and wherein the first source or drain contact comprises nitrogen and carbon, wherein the second source or drain contact comprises tungsten, cobalt, titanium, platinum or ruthenium.

Example 23 includes the subject matter of any of Examples 19-22, and wherein the first source or drain contact comprises tungsten.

Example 24 includes the subject matter of any of Examples 19-23, and wherein the first source or drain contact comprises molybdenum.

Example 25 includes the subject matter of any of Examples 19-24, and wherein the NMOS GAA transistor comprises a first plurality of nanoribbon channels, wherein the first source or drain contact extends deeper than a second nanoribbon channel of the first plurality of nanoribbon channels, wherein the PMOS GAA transistor comprises a second plurality of nanoribbon channels, wherein the second source or drain contact does not extend deeper than a second nanoribbon channel of the second plurality of nanoribbon channels.

Example 26 includes the subject matter of any of Examples 19-25, and wherein the first source or drain region comprises silicon and phosphorous, wherein the second source or drain region comprises silicon, germanium, and boron.

Example 27 includes the subject matter of any of Examples 19-26, and further including a processor, wherein the processor comprises the die.

Example 28 includes the subject matter of any of Examples 19-27, and further including one or more memory devices communicatively coupled to the processor.

1. A device comprising:
a die comprising:
an NMOS gate-all-around (GAA) transistor comprising:
a first source or drain region; and
a first source or drain contact, the first source or drain contact adjacent the first source or drain region; and
a PMOS GAA transistor comprising:
a second source or drain region; and
a second source or drain contact, the second source or drain contact adjacent the second source or drain region,
wherein the first source or drain contact extends a first depth into the first source or drain region, wherein the second source or drain contact extends a second depth into the second source or drain region,
wherein the first depth is at least 10 nanometers deeper than the second depth.

2. The device of claim 1, wherein the NMOS GAA transistor further comprises a first channel region, the first channel region adjacent the first source or drain region,
wherein the PMOS GAA transistor further comprises a second channel region, the second channel region adjacent the second source or drain region,
wherein the first channel region has a first lattice constant, wherein the second channel region has a second lattice constant, wherein the second lattice constant is at least 1% greater than the first lattice constant.

3. The device of claim 1, wherein the first source or drain contact comprises nitrogen and carbon, wherein the second source or drain contact comprises tungsten, cobalt, titanium, platinum, or ruthenium.

4. The device of claim 3, wherein the first source or drain contact comprises tungsten.

5. The device of claim 3, wherein the first source or drain contact comprises molybdenum.

6. The device of claim 1, wherein the first source or drain region comprises silicon and phosphorous, wherein the second source or drain region comprises silicon, germanium, and boron.

7. The device of claim 1, wherein the NMOS GAA transistor comprises a first plurality of nanoribbon channels, wherein the first source or drain contact extends deeper than a second nanoribbon channel of the first plurality of nanoribbon channels,
wherein the PMOS GAA transistor comprises a second plurality of nanoribbon channels, wherein the second source or drain contact does not extend deeper than a second nanoribbon channel of the second plurality of nanoribbon channels.

8. The device of claim 1, further comprising a processor, wherein the processor comprises the die.

9. The device of claim 8, further comprising one or more memory devices communicatively coupled to the processor.

10. A device comprising:
a die comprising:
an NMOS gate-all-around (GAA) transistor comprising:
a first source or drain region;
a second source or drain region; and
a first channel region, wherein the first channel region is adjacent the first source or drain region and the second source or drain region; and
a PMOS GAA transistor comprising:
a third source or drain region;
a fourth source or drain region; and
a second channel region, wherein the second channel region is adjacent the third source or drain region and the fourth source or drain region,
wherein the first channel region has a first lattice constant, wherein the second channel region has a second lattice constant, wherein the second lattice constant is at least 1% greater than the first lattice constant.

11. The device of claim 10, wherein the NMOS GAA transistor further comprises a first source or drain contact, the first source or drain contact adjacent the first source or drain region, wherein the PMOS GAA transistor further comprises a second source or drain contact, the second source or drain contact adjacent the third source or drain region,
wherein the first source or drain contact extends a first depth into the first source or drain region, wherein the second source or drain contact extends a second depth into the third source or drain region,
wherein the first depth is at least 10 nanometers deeper than the second depth.

12. The device of claim 11, wherein the first source or drain contact comprises nitrogen and carbon, wherein the second source or drain contact comprises tungsten, cobalt, titanium, platinum, or ruthenium.

13. The device of claim 12, wherein the first source or drain contact comprises tungsten.

14. The device of claim 12, wherein the first source or drain contact comprises molybdenum.

15. The device of claim 11, wherein the NMOS GAA transistor comprises a first plurality of nanoribbon channels, wherein the first source or drain contact extends deeper than a second nanoribbon channel of the first plurality of nanoribbon channels,
wherein the PMOS GAA transistor comprises a second plurality of nanoribbon channels, wherein the second source or drain contact does not extend deeper than a second nanoribbon channel of the second plurality of nanoribbon channels.

16. The device of claim 10, wherein the first source or drain region comprises silicon and phosphorous, wherein the second source or drain region comprises silicon, germanium, and boron.

17. The device of claim 10, further comprising a processor, wherein the processor comprises the die.

18. A device comprising:
a die comprising:
an NMOS gate-all-around (GAA) transistor comprising a first channel region;
a PMOS GAA transistor comprising a second channel region;
means for applying a tensile strain on the first channel region; and
means for applying a compressive strain on the second channel region.

19. The device of claim 18, wherein the first channel region has a first lattice constant, wherein the second channel region has a second lattice constant, wherein the second lattice constant is at least 1% greater than the first lattice constant.

20. The device of claim 18, wherein the NMOS GAA transistor further comprises a first source or drain region and a first source or drain contact, the first source or drain contact adjacent the first source or drain region, wherein the PMOS GAA transistor further comprises a second source or drain region and a second source or drain contact, the second source or drain contact adjacent the second source or drain region,
wherein the first source or drain contact extends a first depth into the first source or drain region, wherein the second source or drain contact extends a second depth into the second source or drain region,
wherein the first depth is at least 10 nanometers deeper than the second depth.
